(19) United States
(12) Patent Application Publication
(10) Pub. No.: US 2014/0253245 A1
(43) Pub. Date: Sep. 11, 2014

(54) Interference Tolerant, Broadband Radio Frequency Amplifier

(71) Applicant: AURIGA MEASUREMENT SYSTEMS, LLC, Chelmsford, MA (US)

(72) Inventor: Yusuke Tajima, Acton, MA (US)

(73) Assignee: AURIGA MEASUREMENT SYSTEMS, LLC, Chelmsford, MA (US)

(21) Appl. No.: 13/786,721

(22) Filed: Mar. 6, 2013

(51) Int. Cl. H03F 3/193

(52) U.S. Cl. CPC H03F 3/193
USPC 330/295

(57) ABSTRACT

A distributed RF amplifier includes filter circuits to band limit input signal components applied to corresponding amplifiers. Different amplifiers in the distributed amplifier may be band limited to different pass bands. The different pass bands may collectively cover an operational frequency range of the distributed amplifier. In this manner, band-limited interference within an input signal of the distributed amplifier may only effect the gain performance of the distributed amplifier within corresponding band(s)

### FIELD

Subject matter disclosed herein relates generally to radio frequency (RF) circuits and, more particularly, to RE amplifiers and associated techniques.

### BACKGROUND

A current trend in RF communications is toward systems and devices having broad bandwidths. A problem that often arises in broadband systems is increased susceptibility to interference. For example, a large narrowband interferer located anywhere within the operational bandwidth of a broadband amplifier can, in some instances, render the amplifier nonfunctional over its entire bandwidth. This problem may be exacerbated in, for example, multi-functional wireless systems where multiple RF transceivers having different functions are operated in close proximity to one another. The problem may also arise in, for example, military communication systems that are located within hostile territory or in other RF systems subject to jamming or crowded RF environments. There is a need for broadband RF amplifier techniques and architectures that are more tolerant to interference.

### SUMMARY

In accordance with one aspect of the concepts, systems, circuits, and techniques described herein, a distributed radio frequency (RF) amplifier system comprises: an input port to receive an input signal to be amplified; an output port to output an amplified signal; a first transmission medium coupled to the input port; a second transmission medium coupled to the output port; a plurality of amplifiers, each having an input terminal and an output terminal, the input terminal of each amplifier being coupled to a corresponding point on the first transmission medium to receive an input signal component therefrom and the output terminal of each amplifier being coupled to a corresponding point on the second transmission medium to deliver an output signal component thereto, wherein the second transmission medium is configured to combine the output signal components to form the amplified signal; and a plurality of tuned circuits coupled between the first transmission medium and the input terminals of the plurality of amplifiers to provide frequency filtration to corresponding input signal components, the plurality of tuned circuits including a first tuned circuit coupled between the first transmission medium and the input terminal of a first amplifier and a second tuned circuit coupled between the first transmission medium and the input terminal of a second amplifier, the first tuned circuit having a bandpass frequency response with a first frequency passband and the second tuned circuit having a bandpass frequency response with a second frequency passband that is different from the first frequency passband.

In accordance with another aspect of the concepts, systems, circuits, and techniques described herein, a method of operating a distributed RF amplifier comprises: receiving an input signal to be amplified; distributing the input signal to input terminals of a plurality of amplifiers by allowing the input signal to propagate along the first transmission medium, the input terminals of the plurality of amplifiers being coupled to the first transmission medium at various points thereon; filtering input signal components derived from the first transmission medium before the input signal components reach corresponding inputs of the plurality of amplifiers, wherein filtering the input signal components includes limiting input signal components applied to at least one of the amplifiers to a first frequency band and limiting input signal components applied to at least one other of the amplifiers to a second frequency hand that is different from the first frequency hand; collecting output signal components from output terminals of the plurality of amplifiers using a second transmission medium, the output signal components combining together on the second transmission medium; and outputting an amplified signal at an output port coupled to the second transmission medium.

In accordance with a further aspect of the concepts, systems, circuits, and techniques described herein, a distributed radio frequency (RF) amplifier system, comprises: (a) a first distributed amplifier stage having a first transmission medium, a second transmission medium, and a first plurality of amplifiers coupled between the first transmission medium and the second transmission medium at spaced positions there along, wherein at least some of the amplifiers within the first plurality of amplifiers are tuned to operate within a first frequency passband and at least some of the amplifiers within the first plurality of amplifiers are tuned to operate within a second frequency passband that is different from the first frequency passband; and (b) a second distributed amplifier stage comprising: (i) a divider to divide an output signal of the first distributed amplifier stage into first and second signal components; (ii) a first distributed amplifier section to amplify the first signal component, the first distributed amplifier section having a third transmission medium, a fourth transmission medium, and a second plurality of amplifiers coupled between the third transmission medium and the fourth transmission medium at spaced positions there along; (iii) a second distributed amplifier section to amplify the second signal component, the second distributed amplifier section having a fifth transmission medium, a sixth transmission medium, and a third plurality of amplifiers coupled between the fifth transmission medium and the sixth transmission medium at spaced positions there along; and (iv) a combiner to combine output signals of the first and second distributed amplifier sections; wherein at least some of the amplifiers within the second plurality of amplifiers and at least some of the amplifiers within the third plurality of amplifiers are tuned to operate within a third frequency passband that is different from the first and second frequency passbands.

### BRIEF DESCRIPTION OF THE DRAWINGS

The foregoing features may be more fully understood from the following description of the drawings in which:

FIG. 1 is a schematic diagram illustrating an exemplary broadband, distributed low noise amplifier (LNA) in accordance with an embodiment;

FIGS. 2, 3, and 4 are plots illustrating gain performance and input return loss, under different interference scenarios, for a distributed LNA in accordance with an embodiment;

FIG. 5 is a schematic diagram illustrating an exemplary broadband, distributed LNA in accordance with another embodiment; and

FIG. 6 is a schematic diagram illustrating an exemplary distributed LNA that provides enhanced isolation in accordance with an embodiment.

### DETAILED DESCRIPTION

Techniques, circuits, and systems are described herein that are capable of achieving broadband signal amplification in a manner that is more tolerant of in-band interference than conventional broadband approaches. In some embodiments, this may be achieved by providing a distributed amplifier system where different amplifiers ire the system are tuned to different frequency bands. Acting together, the different frequency bands may cover an entire desired bandwidth of the amplifier. In this manner, an interferer within one of the different frequency bands of the distributed amplifier may negatively affect operation of the distributed amplifier within that band, but it won't affect operation over the entire operational bandwidth of the system. In some implementations, the distributed amplifier design may be used to provide broadband low noise amplification for use in communication systems and other RF systems. However, the described techniques may also be used to provide other types of amplifiers.

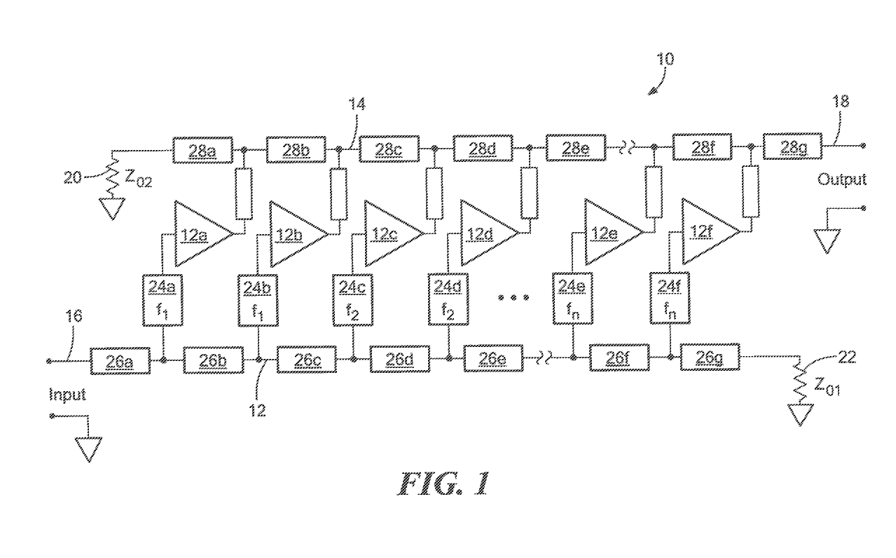

FIG. 1 is a schematic diagram illustrating a broadband, distributed low noise amplifier (LNA) system in accordance with an embodiment. As illustrated, the distributed LNA 10 includes a number of amplifiers 12a-12f having input terminals coupled to a first transmission medium 12 and output terminals coupled to a second transmission medium 14. Although illustrated with six amplifiers 12a-12f, it should be appreciated that any number of amplifiers greater than one may be used. An input port 16 of distributed LNA 10 is coupled to one end of first transmission medium 12. An input signal applied to input port 16 will propagate along first transmission medium 12 to provide input signal components to amplifiers 12a-12f. The output signals of amplifiers 12a-12f are delivered to second transmission medium 14, where they combine to form an amplified output signal at an output port 18 of distributed LNA 10. A matched termination 20 may be provided at an opposite end of second transmission medium 14 to absorb any signal components propagating in an opposite direction on second transmission medium 14 so that they do not reflect back into the medium 14. Likewise, a matched termination 22 may be provided at an end of first transmission medium 12 to absorb the signal propagating along the medium 12 to reduce or eliminate any reflections.

As shown in FIG. 1, first transmission medium 12 may include a series of reactive elements 26a-26g along a length thereof. These elements, together with reactive elements on the corresponding shunt legs, may interoperate to form a quasi-transmission line. Reactive elements 26a-26g may include lumped elements and/or elements implemented using transmission line segments. In some embodiments, reactive elements 26a-26g may include lumped inductors that operate in conjunction with capacitances in the corresponding shunt legs to simulate a transmission line. In a similar manner, second transmission medium 14 may include a series of reactive elements 28a-28g along a length thereof. Reactive elements 28a-28g, along with reactive elements on the corresponding shunt legs, may also interoperate to form a quasi-transmission line.

As illustrated, the input terminals of amplifiers 12a-12f are coupled to points on first transmission medium 12 from which input signal components are received. Similarly, the amplified output signals of amplifiers 12a-12f are delivered to corresponding points on second transmission medium 14. The electrical lengths or phases of the circuitry may be designed so that the output signals of amplifiers 12a-1.2f add in phase on second transmission medium 14 to form a wave that propagates along second transmission medium 14 toward output port 18. Amplifiers 12a-12f may include any type of electronic amplification devices or circuits. In some implementations, each of the amplifiers 12a-12f may include a single transistor (e.g., a field effect transistor (FET), a junction FET (JFET), an insulated gate FET (IGFET), a bipolar junction transistor (BJT), a high electron mobility transistor (HEMT), a pseudomorphic HEMT (pHEMT), a metamorphic HEMT (mHEMT), a heterojunction bipolar transistor (HBT), and/or others). Amplifiers 12a-12f may be implemented using any of a variety of different materials or material combinations including, for example, silicon (Si), germanium (Ge), silicon germanium (SiGe), gallium arsenide (GaAs), aluminum gallium arsenide (AlGaAs), gallium nitride (GaN), gallium indium arsenide (GaInAs), aluminum indium arsenide (AlInAs), indium phosphide (InP), and/or others. In at least one implementation, amplifiers 12a-12f are each implemented using GaN HEMT devices. In other implementations, one or more of amplifiers 12a-12f may include an amplification circuit having one or more transistor stages (e.g., a cascode arrangement, a cascade arrangement, etc.). Other amplifier types may also be used.

In some embodiments, amplifiers 12a-12f may all be of substantially the same design. That is, all of the amplifiers 12a-12f may use the same amplification device, transistor, or multi-stage transistor circuit. In other embodiments, different amplifier designs may be used for the different amplifiers 12a-12f. For example, in one approach, different transistors may be used for amplifiers operating in different passbands. Other arrangements may alternatively be used.

As shown in FIG. 1, in some embodiments, a plurality of filters 24a-24f may be provided between first transmission medium 12 and the input terminals of amplifiers 12a-12f to filter corresponding input signal components being delivered to the amplifiers. The filters 24a-24f may include, for example, bandpass filters each having a frequency passband that allows frequency components within the passband to pass through the filter and frequency components outside of the passband to be blocked by the filter. In some implementations, different ones of the filters 24a-24f may have different frequency responses from other ones of the filters 24a-24f. For example, in the illustrated embodiment, filters 24a, 24b associated with amplifiers 12a, 12b, respectively, have a first passband tuned at a first frequency f₁; filters 24c, 24d associated with amplifiers 12c, 12d have a second passband tuned at a second frequency f₂; and filters 24e, 24f associated with amplifiers 12e, 12f have a third passband tuned at a third frequency f₃. In this manner, amplifiers 12a, 12b will only amplify portions of the input signal applied at input port 16 that are within the first passband, amplifiers 12c, 12d will only amplify portions of the input signal that are within the second passband, and amplifiers 12e, 12f will only amplify portions of the input signal that are within the third passband.

In at least one embodiment, the different passbands associated with filters 24a-24f may be non-overlapping (or substantially non-overlapping). In addition, in some implementations, the passbands associated with filters 24a-24f may be adjacent to one another within a radio frequency spectrum so that, cumulatively, the passbands cover the entire desired operational frequency range of distributed LNA 10. In the embodiment illustrated in FIG. 1, for example, the distributed LNA 10 may have an operational frequency range of 0.5-6 GHz, with the first passband covering a frequency range of 0.5-1.5 GHz, the second passband covering a frequency range of 1.5-3.5 GHz, and the third passband covering a frequency range of 3.5-6 GHz. In the embodiment of FIG. 1, two amplifiers are operative within each of the different passbands. It should be appreciated, however, that in other embodiments, any number of amplifiers may be used in each of the different passbands (i.e., one or more).

As is well known, amplifiers for use at RF frequencies often have parasitic elements associated with them that can affect the performance of the amplifiers. For example, a field effect transistor (FET) may have a gate-to-source capacitance (C_{GS}) and a drain-to-source capacitance (C_{DS}) that can effect RF performance. In some implementations, one or more parasitic elements of an amplifier may be taken into consideration in designing a filter for the amplifier. For example, with reference to FIG. 1, if amplifier 12a is implemented using a FET, the gate-to-source capacitance of the FET may be taken into consideration in the design of the filter 24a to achieve the desired passband. The design of the various filters 24a-24f must also take into consideration the effect of the filters on the propagation characteristics of the first transmission medium 12. Ideally, first transmission medium 12 will behave as a transmission line having a relatively constant characteristic impedance with no major discontinuities that will create reflections of the propagating input signal. In conventional distributed amplifiers, constant-K transmission structures are generally used to achieve this result. Because different filter designs may be used for different amplifiers in the distributed LNA 10 of FIG. 1, additional design steps may need to be taken to achieve a uniform characteristic impedance across first transmission medium 12.

One benefit of using the distributed amplifier architecture of FIG. 1 is an enhanced tolerance to interference. In a conventional distributed amplifier arrangement, a single in-band interferer can compromise gain performance of the distributed amplifier over the entire operational bandwidth thereof. For example, a strong narrowband interference signal at an input of a conventional distributed LNA within an RF receiver can saturate the LNA in a manner that renders the LNA, and the associated receiver, nonfunctional. Using the architecture of FIG. 1, an interferer within one of the passbands of the distributed amplifier will only affect operation Within that sub-band, and not the other sub-bands within the operational bandwidth of the amplifier 10.

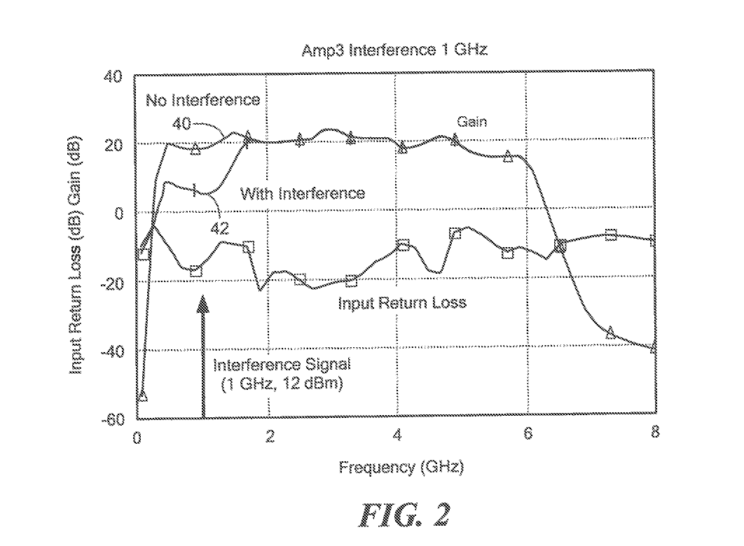

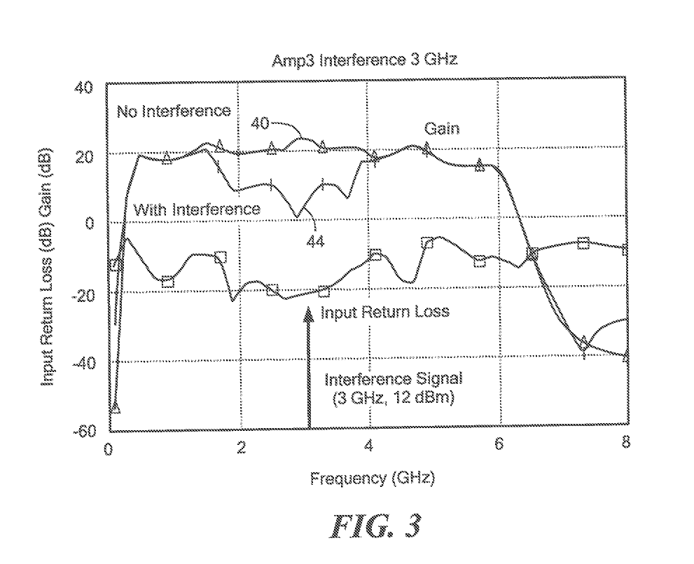

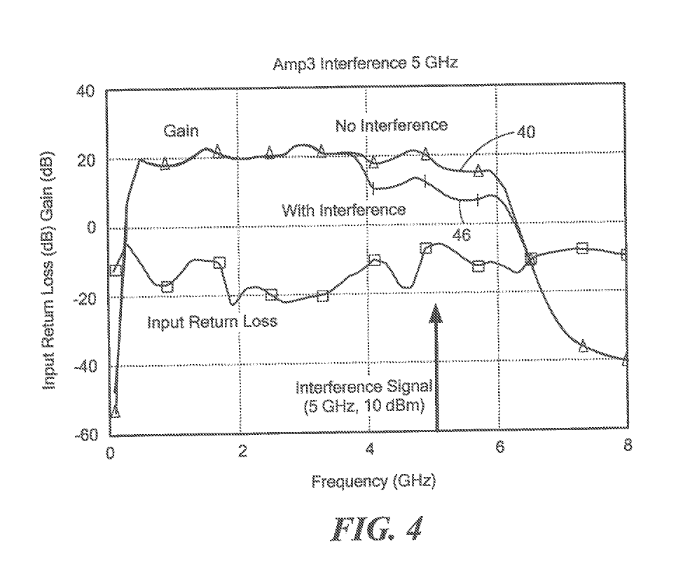

FIGS. 2, 3, and 4 are plots illustrating gain performance and input return loss for a distributed LNA that uses three different passbands (or sub-bands) in accordance with an embodiment, under different interference scenarios. In each of FIGS. 2, 3, and 4, a gain characteristic 40 is shown for operation without interference (illustrated with triangles). As illustrated, the gain characteristic 40 is relatively flat over a wide bandwidth extending from approximately 500 MHz to 6 GHz. FIG. 2 shows the performance of the distributed LNA when a relatively large i.e., 12 dBm) narrowband interferer at a frequency of 1 GHz is present at the input port. FIG. 3 shows the performance when a relatively large narrowband interferer at a frequency of 3 GHz is present at the input port. FIG. 4 shows the performance when a relatively large narrowband interferer at a frequency of 5 GHz is present at the input port.

In each case, the overall gain characteristic degrades to some extent due to the presence of the interferer. However, the reduction in gain. performance only affects the sub-band within which the interferer is located. Outside of this sub-band, the gain performance remains substantially the same as when no interference is present. More specifically, as shown in the FIG. 2, the interferer at 1 GHz reduces the gain of the LNA within a first sub-band 42, but has little to no effect outside of this sub-hand. As shown in FIG. 3, the interferer at 3 GHz reduces the gain of the LNA within a second sub-band 44, but has little to no effect outside of this sub-band. As shown in FIG. 4, the interferer at 5 GHz reduces the gain of the LNA within a third sub-band 46, but has little to no effect outside of this sub-band. In addition to the above, in all three interference scenarios, the input return loss of the distributed LNA remains substantially unaffected.

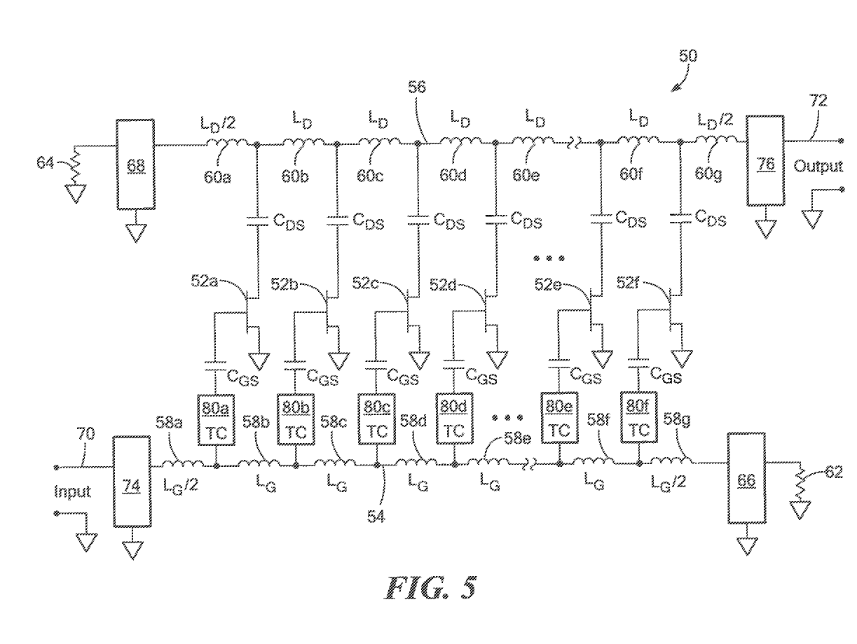

FIG. 5 is a schematic diagram illustrating an exemplary distributed. LNA 50 in accordance with another embodiment. As illustrated, the LNA 50 includes a number of amplifiers 52a-52f coupled between a first transmission medium 54 and a second transmission medium 56. The amplifiers 52a-54f are each implemented using the same transistor device (e.g., a GaN HEMT, etc.) in the illustrated embodiment. The transistors each have a gate-to-source capacitance C_{GS} and a drain-to-source capacitance C_{DS}. First transmission medium 54 includes a series of lumped inductors 58a-58g. In some implementations, the lumped inductors 58a and 58g on the ends of first transmission medium 54 may have an inductance value L_{G}/2 and the lumped inductors 58b-58f between the ends may have an inductance value L_{G}. These inductances may interact with the gate-to-source capacitances of the transistors and other shunt capacitances to form a first quasi-transmission line for the LNA 50. Second transmission medium 56 includes a series of lumped inductors 60a-60g. The lumped inductors 60a and 60g on the ends of second transmission medium 56 may have an inductance value L_{D}/2 and the lumped inductors 58b-58f between the ends may have an inductance value L_{D}. These inductances may interact with the drain-to-source capacitances of the transistors to form a second quasi-transmission line for the LNA 50.

A first termination 62 may be provided for the first transmission medium 54 and a second termination 64 may be provided for the second transmission medium 56. In some embodiments, matching networks 66, 68 may be provided to match the first and second transmission mediums 54, 56 to the corresponding terminations 62, 64. In addition, a matching network 74 may be used to provide an input match looking into input port 70 and a matching network 76 may be used to provide an output match at output port 72. Techniques

As shown in FIG. 5, a plurality of tuned circuits 80a-80f may be provided between first transmission medium 54 and gate terminals of amplifiers 52a-52f. The tuned circuits 80a-80f may each implement a bandpass filter response for an associated amplifier, using a corresponding gate-to-source capacitance C_{GS} as an. element of the filter. As described previously, different passbands may be implemented for different amplifiers in the distributed LNA 50. In some embodiments, the different passbands may be adjacent and anon-overlapping (or only slightly overlapping) and may collectively cover a desired operational frequency range of the distributed LNA 50.

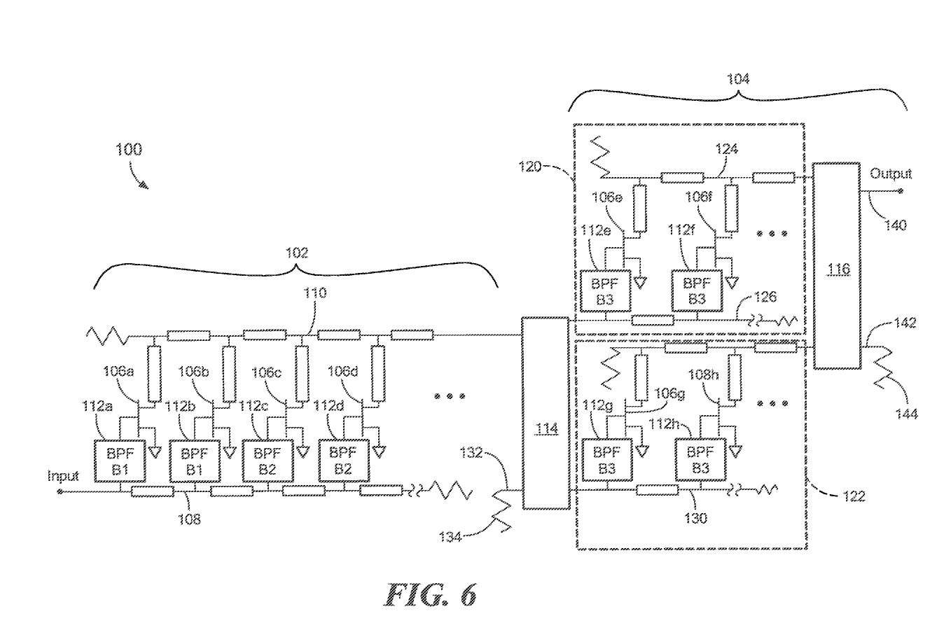

FIG. 6 is a schematic diagram illustrating an exemplary distributed LNA 100 that provides enhanced isolation in accordance with an embodiment. As shown, the distributed LNA 100 includes a first stage 102 and a second stage 104. First stage 102 includes a number of amplifiers 106a-106d coupled between first and second transmission media 108, 110. Each amplifier 106a-106d has a corresponding bandpass filter 112a-112d coupled between the first transmission medium and a gate terminal thereof. As in previous embodiments, the bandpass filters 112a-112d may each be tuned to different pass bands. In the illustrated embodiment, for example, the bandpass filters 112a, 112b associated with amplifiers 106a and 106b are tuned to a first passband (B1) and the bandpass filters 112c, 112d associated with amplifiers 106c and 106d are tuned to a second passband (B2) that is different from the first passband.

One end of the first transmission medium 108 serves as the input of the distributed LNA 100. An end of the second transmission medium 110 is coupled to an input port of a first 90-degree hybrid coupler 114. First 90-degree hybrid coupler 114 splits the signal from first stage 102 into two equal-amplitude signal components that are 90 degrees out of phase at two output ports thereof. The two output signal components feed into first and second distributed amplifier sections 120, 122 of the second stage 104 that operate in parallel. A fourth port 132 of the first 90-degree hybrid coupler 114 may be terminated in a matched termination 134. In this manner, any signal reflections from the first and second distributed amplifier sections 120, 122 will flow back through the coupler 114 to the fourth port 132 and be dissipated in the termination 134. The first 90-degree hybrid coupler 114 may thus provide some degree of isolation between the first and second stages of the distributed LNA 100.

The first distributed amplifier section 120 of the second stage 104 includes a number of amplifiers 106e, 106f coupled between third and fourth transmission media 124, 126. Likewise, the second distributed amplifier section 122 includes a number of amplifiers 106g, 106h coupled between fifth and sixth transmission media 128, 130. As in the first stage 102 of the distributed LNA 100, each amplifier 106e-106h in second stage 104 has a corresponding bandpass filter 112e-112h coupled to a gate terminal thereof. In the illustrated embodiment, all bandpass filters 112e-112h in the second stage 104 are tuned to operate with a common passband (B3). In at least one embodiment, the common passband (B3) of the bandpass filters 112e-112h (and amplifiers) of the second. stage 104 encompasses all of the frequency passbands of the first stage 102. Thus, if the first stage 102 only has filters operative within the first passband (B1) and the second passband (B2), then the common passband (B3) of the second stage 104 may be wide enough to encompass both B1 and B2.

The outputs of the first and second distributed amplifier sections 120, 122 of the second stage 104 of distributed amplifier 100 are coupled to inputs of a second 90-degree hybrid coupler 116. Second 90-degree hybrid coupler 116 combines the signals to generate a single output signal at an output port 140. Because the output signals of two distributed amplifier sections 120, 122 are being combined, higher output power levels are possible. A fourth port 142 of second hybrid coupler 116 may be terminated in a matched termination 144.

Although illustrated with four amplifiers in first stage 102, it should be appreciated that any number of amplifiers (i.e., greater than one) may be used in this stage. Likewise, although illustrated with four amplifiers in the second stage 104, it should be appreciated that any number of amplifiers (i.e., greater than one per distributed amplifier section) may be used in the second stage 104. In addition, in the illustrated embodiment, first stage 102 has bandpass filters/amplifiers that cover two different passbands. It should be appreciated that, in other embodiments, the first stage 102 may include filters/amplifiers covering any number of different passbands (i.e., one or more). Likewise, second stage 104 may include filters/amplifiers covering any number of different passbands (i.e., one or more), as long as the combined band of the second stage 104 encompasses the full combined band of the first stage 102.

In the embodiment of FIG. 6, first stage 102 includes two amplifiers that are tuned within each corresponding passband (e.g., two amplifiers 106a, 106b are tuned to passband B1, two amplifiers 106c, 106d are tuned to passband B2, etc.). It should be appreciated that, in other embodiments, any number of amplifiers (i.e., one or more) within first stage 102 may be tuned to each corresponding passband. This is also the case in second stage 104. In some embodiments, the covered passbands within a stage may be adjacent to one another and non-overlapping (or only slightly overlapping).

In, the embodiment of FIG. 6, 90-degree hybrid couplers 114, 116 are used as divider/combiner structures. It should be appreciated that other types of divider/combiner structures may alternatively be used. In addition, in some embodiments, more than two distributed amplifier stages may be provided. For example, with reference to FIG. 6, in at least one embodiment, the outputs of the first and second distributed amplifier sections 120, 122 of the second stage 104 may be further split by other 90-degree hybrids to feed four distributed amplifier sections in a third stage. The outputs of the four distributed amplifier sections in the third stage may then be combined using additional combiner structures (e.g., two stages of 90-degree hybrid combiners, etc.).

In the embodiments discussed above, inventive features and concepts are described in the context of a broadband LNA. It should be appreciated, however, that the described features and concepts also have application in other types of amplification systems, including amplifiers that are not capable of low noise operation (e.g., power amplifiers, etc.). In addition, in some embodiments described above, the passbands associated with the various amplifiers are described as being adjacent and non-overlapping. It should be appreciated, however, that embodiments using partially overlapping passbands and/or passbands that are separated by a frequency gap (i.e., non-adjacent) may be used in some implementations. The techniques and structures described herein may be implemented using discrete components and/or as integrated circuits. In some implementations, a distributed amplifier in accordance with techniques and concepts disclosed herein may be embodied as a separate monolithic microwave integrated circuit (MMIC) amplifier chip or as a packaged MMIC amplifier. In some other implementations, a distributed amplifier in accordance with techniques and concepts disclosed herein may be implemented as part of a larger system on an MMIC, system on chip (SoC), multi-chip module, or other integrated circuit arrangement.

Having described exemplary embodiments of the invention, it will now become apparent to one of ordinary skill in the art that other embodiments incorporating their concepts may also be used. The embodiments contained herein should not be limited to disclosed embodiments, but rather should be limited only by the spirit and scope of the appended claims. All publications and references cited herein are expressly incorporated herein by reference in their entirety.

What is claimed is:

1. A distributed radio frequency (RF) amplifier system, comprising:
an input port to receive an input signal to be amplified;
an output port to output an amplified signal;
a first transmission medium coupled to the input port;
a second transmission medium coupled to the output port;
a plurality of amplifiers, each having an input terminal and an output terminal, the input terminal of each amplifier being coupled to a corresponding point on the first transmission medium to receive an input signal component therefrom and the output terminal of each amplifier being coupled to a corresponding point on the second transmission medium to deliver an output signal component thereto, wherein the second transmission medium is configured to combine the output signal components to form the amplified signal; and
a plurality of tuned circuits coupled between the first transmission medium and the input terminals of the plurality of amplifiers to provide frequency filtration to corresponding input signal components, the plurality of tuned circuits including a first tuned circuit coupled between the first transmission medium and the input terminal of a first amplifier and a second tuned circuit coupled between the first transmission medium and the input terminal of a second amplifier, the first tuned circuit having a bandpass frequency response with a first frequency passband and the second tuned circuit having a bandpass frequency response with a second frequency passband that is different from the first frequency passband.

2. The distributed RF amplifier system of claim 1, wherein:
the first frequency passband and the second frequency passband are non-overlapping.

3. The distributed RF amplifier system of claim 1, wherein:
the first frequency passband and the second frequency passband each represent portions of an overall frequency response of the distributed RF amplifier.

4. The distributed RF amplifier system of claim 1, wherein:
the plurality of tuned circuits includes a third tuned circuit coupled between the first transmission medium and the input terminal of a third amplifier, the third tuned circuit having a bandpass frequency response with the first frequency passband.

5. The distributed RF amplifier system of claim 1, wherein:
the plurality of tuned circuits further includes a third tuned circuit coupled between the first transmission medium and the input terminal of a third amplifier, the third tuned circuit having a bandpass frequency response with a third frequency passband that is different from the first and second frequency passbands.

6. The distributed RF amplifier system of claim 1, wherein:
the plurality of tuned circuits includes at least one tuned circuit for each of a number of different frequency passbands, wherein the number of different frequency passbands cumulatively cover an operational bandwidth of the distributed RF amplifier.

7. The distributed RF amplifier system of claim 6, wherein:
the plurality of tuned circuits includes multiple tuned circuits for each of the number of different frequency passbands.

8. The distributed RF amplifier system of claim 6, wherein:
the distributed RF amplifier has a gain response that covers the operational bandwidth, the gain response being susceptible to interference components within the input signal of the distributed RF amplifier, wherein an interference component in the input signal that is limited to one of the number of different frequency passbands will only significantly affect the gain response of the distributed RF amplifier within that one passband.

9. The distributed RF amplifier system of claim 1, wherein:
the distributed RF amplifier is a low noise amplifier (LNA).

10. The distributed RF amplifier system of claim 1, wherein:
the plurality of amplifiers includes at least two different amplifier designs.

11. A method of operating a distributed RF amplifier, the method comprising:
receiving an input signal to be amplified;
distributing the input signal to input terminals of a plurality of amplifiers by allowing the input signal to propagate along the first transmission medium, the input terminals of the plurality of amplifiers being coupled to the first transmission medium at various points thereon;
filtering input signal components derived from the first transmission medium before the input signal components reach corresponding inputs of the plurality of amplifiers, wherein filtering the input signal components includes limiting input signal components applied to at least one of the amplifiers to a first frequency band and limiting input signal components applied to at least one other of the amplifiers to a second frequency band that is different from the first frequency band;
collecting output signal components from output terminals of the plurality of amplifiers using a second transmission medium, the output signal components combining together on the second transmission medium; and
outputting an amplified signal at an output port coupled to the second transmission medium.

12. The method of claim 11, wherein:
the first frequency band and the second frequency hand are non-overlapping.

13. The method of claim 11, wherein:
filtering input signal components includes limiting input signal components applied to the inputs of the plurality of amplifiers to one of N frequency bands, wherein N is a positive integer greater than one, wherein each of the N frequency bands is used with at least one amplifier in the plurality of amplifiers, wherein the N frequency bands are adjacent bands.

14. The method of claim 13, wherein:
each of the N frequency bands is used with multiple amplifiers in the plurality of amplifiers.

15. The method of claim 13, wherein:
the N frequency bands collectively cover an operational bandwidth of the distributed RF amplifier.

16. A distributed radio frequency (RF) amplifier system, comprising;
a first distributed amplifier stage having a first transmission medium, a second transmission medium, and a first plurality of amplifiers coupled between the first transmission medium and the second transmission medium at spaced positions there along, wherein at least some of the amplifiers within the first plurality of amplifiers are tuned to operate within a first frequency passband and at least some of the amplifiers within the first plurality of amplifiers are tuned to operate within a second frequency passband that is different from the first frequency passband; and
a second distributed amplifier stage comprising:
a divider to divide an output signal of the first distributed amplifier stage into first and second signal components;
a first distributed amplifier section to amplify the first signal component, the first distributed amplifier section having a third transmission medium, a fourth transmission medium, and a second plurality of amplifiers coupled between the third transmission medium and the fourth transmission medium at spaced positions there along;
a second distributed amplifier section to amplify the second signal component, the second distributed amplifier section having a fifth transmission medium, a sixth transmission medium, and a third plurality of amplifiers coupled between the fifth transmission medium. and the sixth transmission medium at spaced positions there along; and
a combiner to combine output signals of the first and second distributed amplifier sections;
wherein at least some of the amplifiers within the second plurality of amplifiers and at least some of the amplifiers within the third plurality of amplifiers are tuned to operate within a third frequency passband that is different from the first and second frequency passbands.

17. The distributed RF amplifier system of claim 16, wherein:
the third frequency passband encompasses the first and second frequency passbands.

18. The distributed RF amplifier system of claim 16, wherein:
the first and second frequency passbands are non-overlapping.

19. The distributed RF amplifier system of claim 16, wherein:
the first and second frequency passbands are adjacent to one another.

20. The distributed RF amplifier system of claim 16, wherein:
at least some of the amplifiers within the first plurality of amplifiers are tuned to operate within a frequency passband other than the first and second frequency passbands.

21. The distributed RF amplifier system of claim 16, wherein.;
at least some of the amplifiers within the second plurality of amplifiers are tuned to operate within a frequency passband other than the third frequency passband.
